(19) United States
(12) Patent Application Publication
(10) Pub. No.: US 2026/0157220 A1
(43) Pub. Date: Jun. 4, 2026

(54) SEMICONDUCTOR DEVICE AND METHOD OF FABRICATING AN ELECTRICALLY CONDUCTIVE STRUCTURE OF A METALLIZATION STRUCTURE

(71) Applicant: Infineon Technologies Austria AG, Villach (AT)

(72) Inventors: Markus Augustin, Hutthurm (DE); Stefan Lipps, Wenzenbach (DE)

(21) Appl. No.: 19/404,526

(22) Filed: Dec. 1, 2025

(30) Foreign Application Priority Data
Dec. 2, 2024 (EP) 24216936

(51) Int. Cl. H01L 23/00; H01L 21/56; H01L 23/31

(52) U.S. Cl. CPC H10W 74/01; H10W 74/147; H10W 72/01935; H10W 72/01953; H10W 72/01955; H10W 72/90; H10W 72/923; H10W 72/934; H10W 72/952

(57) ABSTRACT

In an embodiment, a semiconductor device is provided that includes a semiconductor substrate having a first major surface and a metallization structure located on the first major surface. The metallization structure includes one or more electrically conductive structures having a metallic diffusion barrier layer and a copper layer located on the metallic diffusion barrier layer. The metallic diffusion barrier layer has a thickness t, an upper surface, a lower surface, and a side face extending between an upper edge formed between the upper surface and the side face and a lower edge formed between the lower surface and the side face. The linear distance d between the upper edge and the lower edge is t≤d≤1.1 t or t≤d≤1.05 t.

### BACKGROUND

Transistors used in power electronic applications may be fabricated with silicon (Si) semiconductor materials. Common transistor devices for power applications include Si CoolMOS®, Si Power MOSFETs, and Si Insulated Gate Bipolar Transistors (IGBTs). More recently, silicon carbide (SiC) power devices have been considered. Group III-N semiconductor devices, such as gallium nitride (GaN) devices, are attractive candidates to carry large currents, support high voltages and to provide very low on-resistance and fast switching times.

One or more semiconductor devices, e.g. transistor devices, may be provided in a package. The package includes a substrate or a leadframe which includes outer contacts which are used to mount the package on a redistribution board such as a printed circuit board. The package also includes internal electrical connections from the semiconductor device to the substrate or leadframe. The housing may include a plastic molding compound which covers the semiconductor device and the internal electrical connections.

Reliable semiconductor devices and packaged semiconductor devices are desirable. US 2018/0308927 A1 describes structures and methods for isolating semiconductor devices and improving device reliability under harsh environmental conditions. An isolation region is formed by ion implantation in a region of semiconductor surround-ing a device. The implantation region may extend into streets of a wafer. A passivation layer is deposited over the implantation region and extends further into the streets than the isolation region to protect the isolation region from environmental conditions that may adversely affect the isolation region.

Further improvements to the reliability of devices, also under harsh environmental conditions, are desirable.

### SUMMARY

In an embodiment, a semiconductor device is provided that comprises a semiconductor substrate comprising a first major surface and a metallization structure located on the first major surface. The metallization structure comprises one or more electrically conductive structures comprising a metallic diffusion barrier layer and a copper layer located on the metallic diffusion barrier layer. The metallic diffusion barrier layer has a thickness t, an upper surface, a lower surface and a side face extending between an upper edge formed between the upper surface and the side face and a lower edge formed between the lower surface and the side face. The linear distance d between the upper edge and the lower edge is t≤d≤1.1 t or t≤d≤1.05 t.

In an embodiment, a method of fabricating an electrically conductive structure of a metallization structure is provided. The method comprises forming a metallic diffusion barrier layer on a first major surface of a semiconductor substrate, forming a structured copper layer on the metallic diffusion barrier layer, wherein portions of the metallic diffusion barrier layer are exposed from the structured copper layer, removing the exposed portions of the metallic diffusion barrier layer by plasma etching and forming one or more electrically conductive structures comprising the metallic diffusion barrier layer and the copper layer.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Exemplary embodiments are depicted in the drawings and are detailed in the description which follows.

FIG. 1 illustrates a cross-sectional view of a semiconductor device including a metallization structure.

FIG. 2 illustrates a flow diagram of a method of fabricating an electrically conductive structure of a metallization structure.

FIGS. 3A to 3G illustrate a method of fabricating a metallization structure on a semiconductor device.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of exemplary embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A depletion-mode device, such as a high-voltage depletion-mode transistor, has a negative threshold voltage which means that it can conduct current at zero gate voltage. These devices are normally on. An enhancement-mode device, such as a low-voltage enhancement-mode transistor, has a positive threshold voltage which means that it cannot conduct current at zero gate voltage and is normally off.

In some embodiments, the semiconductor device is a Group III nitride-based device, such as a transistor device, a diode or a bidirectional switch.

As used herein, the phrase “Group III-Nitride” refers to a compound semiconductor that includes nitrogen (N) and at least one Group III element, including aluminum (Al), gallium (Ga), indium (In), and boron (B), and including but not limited to any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐPbN_{(1-a-b)}), and aluminum indium gallium arsenide phosphide nitride (AlₓIn_{y}Ga_{(1-x-y)}AsₐPbN_{(1-a-b)}), for example. Aluminum gallium nitride and AlGaN refer to an alloy described by the formula AlₓGa₍₁₋ₓ₎N, where 0<x<1.

As used herein, various device types and/or doped semiconductor regions may be identified as being of n type or p type, but this is merely for convenience of description and not intended to be limiting, and such identification may be replaced by the more general description of being of a “first conductivity type” or a “second, opposite conductivity type” where the first type may be either n or p type and the second type then is either p or n type.

In some embodiments, the semiconductor device is a silicon-based device such as a nitride-based MOSFET (Metal Oxide Semiconductor Field Effect Transistor) device, an insulated gate bipolar transistor (IGBT) device or a Bipolar Junction Transistor (BJT). The transistor device may be a vertical transistor device with a drift path that extends perpendicularly to the major surfaces of the device.

The electrodes or terminals of the transistor device are referred to herein as source, drain and gate. As used herein, these terms also encompass the functionally equivalent terminals of other types of transistor devices, such as an insulated gate bipolar transistor (IGBT). For example, as used herein, the term “source” encompasses not only a source of a MOSFET device and of a superjunction device but also an emitter of an insulator gate bipolar transistor (IGBT) device and an emitter of a Bipolar Junction Transistor (BJT) device, the term “drain” encompasses not only a drain of a MOSFET device or of a superjunction device but also a collector of an insulator gate bipolar transistor (IGBT) device and a collector of a BJT device, and the term “gate” encompasses not only a gate of a MOSFET device or of a superjunction device but also a gate of an insulator gate bipolar transistor (IGBT) device and a base of a BJT device.

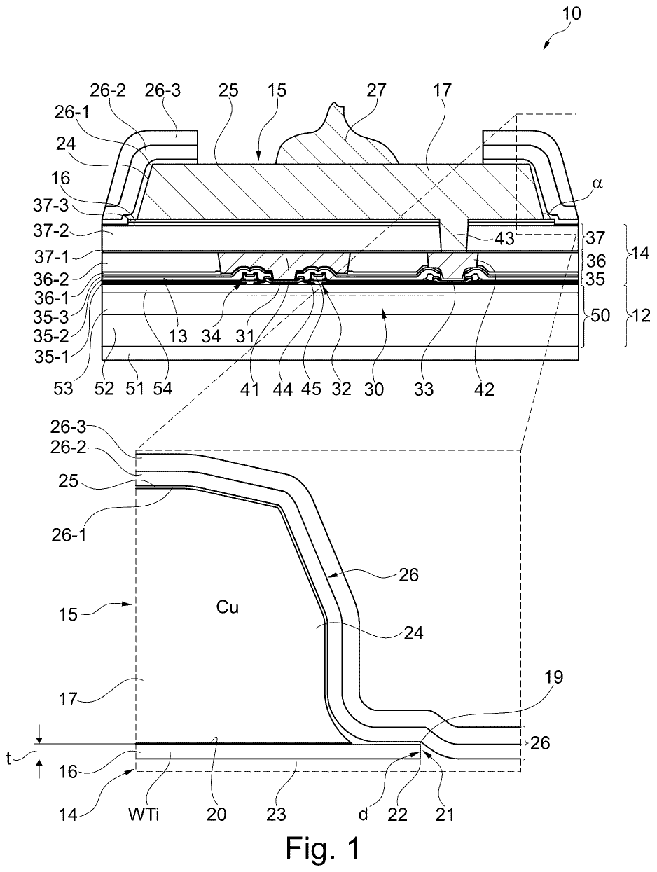

FIG. 1 illustrates a cross-sectional view of a semiconductor device 10 and an enlarged view of a portion of the semiconductor device 10.

The semiconductor device 10 comprises a semiconductor substrate 12 comprising a first major surface 13 on which a metallization structure 14 is located. The metallization structure 14 comprises one or more electrically conductive structures 15. In FIG. 1, the electrically conductive structure 15 has the form of a contact pad. The electrically conductive structure 15 may be described as a portion, part, piece or section and forms part of an electrically conductive layer of the metallization structure, in some embodiments the uppermost electrically conductive layer. The electrically conductive structure 15 may also be referred to as a part of the power metal. The electrically conductive structure 15 is not limited to the form of a contact pad may have other forms, for example a metallic interconnect, for example a gate runner, or a metallic interconnect which extends between two or more devices formed in the semiconductor substrate 12.

The contact pad 15 comprises a metallic diffusion barrier layer 16 and a copper layer 17 which is arranged on, and forms an interface with, the metallic diffusion barrier layer 16. The metallic diffusion barrier layer 16 has an upper surface 20 which is in contact with the copper layer 17 and a lower surface 23 which is in contact with a portion of the metallization structure 14, in this case the third sublayer 37-3 of the third electrically insulating layer 37. The metallic diffusion barrier layer 16 a thickness t and a side face 21, which can also be described as an end face 21, which extends between an upper edge 19, which is formed between the upper surface 20 and the side face 21 of the metallic diffusion barrier layer 16, and a lower edge 22, which is formed between the lower surface 23 and the side face 21 of the metallic diffusion barrier layer 16. The side face 21, which extends between the upper edge 19 and the lower edge 22, has a length such that the linear distance, i.e. the closest distance or spacing, between the upper edge 19 and the lower edge 22 has a distance d.

The side face 21 extends substantially perpendicularly to the upper surface 20 and lower surface 23 of the metallic diffusion barrier layer 16. Consequently, the length of the side face 21 and the linear distance d between the upper edge 19 and the lower edge 22 is approximately the same as the thickness t of the metallic diffusion barrier layer 16. The side face 21 may not extend exactly perpendicularly to the upper surface 20 and the lower surface 23, but is slightly inclined. Consequently, the distance d may be up to 10% greater than the thickness t or up to 5% greater than the thickness t such that t≤d≤1.1 t or t≤d≤1.05 t.

In some embodiments, as illustrated in FIG. 1, the metallic diffusion barrier layer 16 has a lateral extent which is greater than the lateral extent of the copper layer 17 of the contact pad 15 such that the metallic diffusion barrier layer 16 protrudes from the copper layer 17 and has an outer peripheral edge portion which is exposed from, and uncovered by, the copper layer 17 of the contact pad 15. As a result, the side faces 24 of the copper layer 17 of the contact pad 15 extend from the upper surface 25 of copper layer 15 to a position intermediate the upper surface 20 of the metallic diffusion barrier layer 16.

In some embodiments, such as that illustrated in FIG. 1, the side face 24 of the copper layer 17 forms an angle α with the metallic diffusion barrier layer 16 which is greater than 90°. For example, the angle α may be around 105°. In some embodiments, 90°≤α≤145°. The angle may be measured between a tangent of the centre of the height of the copper layer 17 and the upper surface 20 of the metallic diffusion barrier layer 16.

In some embodiments, the semiconductor device 10 further comprises an upper dielectric layer 26 which is located on at least the side faces 24 of the contact pad 15 and, optionally, a peripheral edge region of the upper surface 25, and also on regions of the metallization structure 14 that are located laterally adjacent to the contact pad 15. The dielectric layer 26 is in direct contact with the peripheral region of the upper surface 25 and the side face 24 of the copper layer 17 and with the metallic diffusion barrier layer 16.

The central portion of the upper surface 25 of the contact pad 15 remains exposed from the dielectric layer 26 and provides a contact surface onto which, for example, a bond wire 27 or other connector, such as a ribbon, or a clip or solder, may be attached to provide electrical connection to the semiconductor device or devices located within the semiconductor substrate 12. In the case that the electrically conductive structure 15 provides a metal interconnect, also known as a trace or a line, the entire upper surface 25 of the interconnect may be covered by the dielectric layer 26. In the case that the electrically conductive structure 15 is an interconnect, it is also possible for the upper surface to be partially covered or completely uncovered.

The semiconductor substrate 12 may be formed of silicon. In some embodiments, the semiconductor substrate 12 may be formed of an alternative semiconductor material, such as silicon carbide or may comprise one or more Group III nitride layers. The metallic diffusion barrier layer 16 may comprise a WTi alloy or may be formed by depositing two or more sublayers, for example Ti/TiN or TaN/Ti. The metallic diffusion barrier layer 16 may be deposited by sputtering for example. Any metal or alloy or combination of metals and alloys which are suitable as a diffusion barrier for an upper copper layer 17 may be used. The copper layer 17 may be formed of copper only or may include a smaller fraction of one or more alloying elements, e.g. Al.

The upper dielectric layer 26 may be formed of an oxide, for example silicon oxide, or nitride, for example silicon nitride. The upper dielectric layer 26 may also comprise two or more sublayers. In the illustrated embodiment, the upper dielectric layer 26 comprises three sublayers. A first sublayer 26-1, for example formed of a nitride such as silicon nitride, is in direct contact with the peripheral edge region of the upper surface 25 of the copper layer 17, and the side face 24 of the copper layer 17, with the metallic diffusion barrier layer 16 and portions of the metallization structure 14 that laterally surround the contact pad 15 and any other electrically conductive structures 15 that are present. A second sublayer 26-2 comprising oxide, for example silicon oxide, is arranged on the first sublayer 26-1 and a third sublayer 26-3 comprising silicon nitride is formed on the second sublayer 26-2.

During the operational lifetime of the semiconductor device 10, thermomechanical stress is exerted on the passivation structure including the dielectric layer 26. The upper dielectric layer 26 may be uniformly, continuously and uninterruptedly deposited onto the electrically conductive structure 15 due to the shape of the copper layer 17 and exposed peripheral region of the metallic diffusion barrier layer 16 with its substantially vertical side face. This arrangement assists in improving the integrity of the dielectric layer 26. The passivation integrity of the dielectric layer 26 is improved also in harsh environmental conditions. Improved integrity of the dielectric layer 26 may assist in providing protection from mobile ions, such as chlorine ions, which may leak from the environment and/or the mold compound that is used to provide the housing of the package in which the semiconductor device 10 is mounted. Thus, electrical isolation of the contact pads 15 of the semiconductor device 10 from one another is improved. For example, this is useful for the source and drain contact pads of a transistor device which are typically connected to ground potential and a high potential, respectively. For some Group III nitride-based HEMTs the potential difference may be up to 650V.

In some embodiments, the transition between the side face 24 of the copper layer 17 and the metallic diffusion barrier layer 16 may have a concave form which may further assist in enabling the production of a uniform and continuous dielectric layer 26 on the contact pad 15, metallic diffusion barrier layer 16 and the electrically insulating layer provided by the metallization structure 14 in regions adjacent to the contact pad 15, thus improving the reliability of the semiconductor device 10.

One or more semiconductor devices are formed in the semiconductor substrate 12 which are electrically connected to the metallization structure 14 and to the contact pad 15 and one or more further electrically conductive structures 15 which cannot be seen in the cross-sectional vies of FIG. 1. In the embodiment illustrated in FIG. 1, the semiconductor substrate 12 comprises multilayer Group III nitride-based structure 30 and a Group III nitride transistor device 30. The Group III nitride transistor device has a source electrode 31, a gate electrode 32 and drain electrode 33 located on the first major surface 13 of the semiconductor substrate 12. The gate electrode 32 is located laterally between the source electrode 31 and the drain electrode 33.

In some embodiments, the metallization structure 14 comprises a multilayer stack comprising a first electrically conductive layer 34 in which the terminals of the transistor device 30 are located. In FIG. 1, the source electrode 31 the gate electrode 32 and the drain electrode 33 formed on the first major surface 13 of the semiconductor substrate 12.

The metallization structure 14 comprises a first electrically insulating layer 35 which extends over the first major surface 12 and the gate electrode 32 and which leaves a central portion of the source electrode 31 and drain electrode 33 uncovered. The first electrically insulating layer 35 comprises three sublayers, a lower sublayer 35-1 formed of silicon nitride, a second sublayer 35-2 formed of silicon oxide arranged on the first sublayer 35-1 and a third sublayer 35-3 formed of silicon nitride on the second sublayer 35-2. The second sublayer 35-2 formed of silicon oxide has a greater thickness than the first and third sublayers 35-1, 35-3 formed of silicon nitride.

The metallization structure 14 further comprises a second electrically insulating layer 36 which is positioned on the first electrically insulating layer 35 and a third electrically insulating layer 37 which is arranged on the second electrically insulating layer 36. The second electrically insulating layer 36 comprises two sublayers, a lower first sublayer 36-1 formed of silicon nitride that is in direct contact with the nitride sublayer 35-3, and a second sublayer 36-2 formed of silicon oxide that is arranged on the first sublayer 36-1. The second sublayer 36-2 formed of silicon oxide has a greater thickness than the first sublayer 36-1 formed of silicon nitride.

The third electrically insulating layer 37 comprises three sublayers, a lower sublayer 37-1 formed of silicon nitride that is located directly on the oxide sublayer 36-2, a second sublayer 37-2 formed of silicon oxide arranged on the first sublayer 37-1 and a third sublayer 37-3 formed of silicon nitride on the second sublayer 37-2. The second sublayer 37-2 formed of silicon oxide has a greater thickness than the first and third sublayers 37-1, 37-3 formed of silicon nitride. The upper surface of the third sublayer 37-3 is in contact with the metallic diffusion barrier layer 16 of the contact pad 15.

A first redistribution portion 41 is located in the second electrically insulating layer 36 and further extends through the first electrically insulating layer 35 to contact the source electrode 31. A second separate redistribution portion 42 is located in the second electrically insulating layer 36 which extends through the first electric insulating layer 35 to the drain electrode 33. The first and second redistribution portions 41, 42 extend through the thickness of the second electrically insulating layer 36.

In the cross-sectional view of FIG. 1, the redistribution structure from the drain electrode 33 to the contact pad 15 is shown such that the contact pad 15 provides the drain pad. A conductive via 43 extends through the third electrically insulating layer 37 so as to electrically connect the contact pad 15 with the redistribution portion 42 which is in turn electrically connected to the drain electrode 33. In some embodiments, an additional metal layer can be formed between the conductive via 43 and the contact 42 to improve the adhesion.

The source and gate contact pad of the transistor device cannot be seen in the cross-sectional view of FIG. 1 but have the structure of the drain contact pad 15 illustrated in and described with reference to FIG. 1. For example, the source and gate pad may be positioned in a plane in front of or behind the plane of the drawing.

The multilayer Group III nitride structure of the semiconductor substrate 12 is illustrated in FIG. 1. The Group III nitride structure 50 is arranged on a substrate 51. The Group III nitride body comprises a buffer structure 52 on the substrate 51, a GaN channel layer 53 on the buffer layer and an AlGaN barrier layer 54 on the GaN channel layer 53 which forms a heterojunction therebetween which supports a two-dimensional charge gas such as a two-dimensional electron gas (2DEG). The transistor device 30 may be a HEMT (High Electron Mobility Transistor). In this embodiment, the AlGaN barrier layer 54 forms the upper surface 14 of the Group III nitride structure 50.

The substrate 51 includes an upper or growth surface 55 which is capable of supporting the epitaxial growth of one or more Group III nitride-based layers. In some embodiments, the substrate 51 is a foreign substrate, i.e. is formed of a material other than Group III nitride materials that includes the upper or growth surface 33 which is capable of supporting the epitaxial growth of the one or more Group III nitride-based layers. The foreign substrate 51 may be formed of silicon and may be formed of monocrystalline silicon or an epitaxial silicon layer, for example, or sapphire.

In some non-illustrated embodiments, the Group III nitride-based semiconductor structure 50 may further include a back barrier layer. The GaN channel layer 53 is formed on the back barrier layer and forms a heterojunction with the back barrier layer and the barrier layer 54 is formed on channel layer 53. The back barrier layer has a different bandgap to the GaN channel layer and may comprise AlGaN, for example. The composition of the AlGaN of the back barrier layer may differ from the composition of the AlGaN used for the barrier layer 54.

A typical transition or buffer structure 52 for a silicon substrate includes a AlN starting layer, which may have a thickness of several 100 nm, on the silicon substrate followed by a AlₓGa₍₁₋ₓ₎N layer sequence, the thickness again being several 100 nm's for each layer, whereby the Al content of about 50-75% is decreased down to 10-25% before the GaN layer or AlGaN back barrier, if present, is grown. Alternatively, a superlattice buffer can be used. Again, an AlN starting layer on the silicon substrate is used. Depending on the chosen superlattice, a sequence of AlN and AlₓGa₍₁₋ₓ₎N pairs is grown, where the thickness of the AlN layer and AlₓGa₍₁₋ₓ₎N is in the range of 2-25 nm. Depending on the desired breakdown voltage the superlattice may include between 20 and 100 pairs. Alternatively, an AlₓGa₍₁₋ₓ₎N layer sequence as described above can be used in combination with the above mentioned superlattice.

The gate electrode 32 may include a p doped Group III nitride layer 44, for example p-doped gallium nitride, and a gate metal layer 45 which is arranged on the p doped Group III nitride layer 44. This structure for the gate electrode 32 provides an enhancement mode device which is normally off. In other embodiments, the gate electrode 32 may have a recessed structure to from an enhancement mode device. Alternatively, the Group III nitride-based transistor device 30 may be a depletion mode device.

In alternative embodiments, the semiconductor substrate 12 may also be formed of other semiconductor materials, such as silicon carbide or silicon. In some embodiments, the semiconductor substrate 12 is formed of an epitaxial silicon layer. For example, the semiconductive device 30 may be a silicon-based MOSFET, IGBT or BJT.

In the illustrated embodiments, the semiconductor device 10 comprises a lateral transistor device. However, the semiconductor device 10 may comprise other types of devices, for example other types of transistor device, such as vertical transistor devices, a bidirectional switch, a diode, two or more semiconductor devices such as a transistor device and a gate driver device, a power device and a logic device, or two transistor devices electrically connected by the metallization structure to provide a half-bridge circuit, or a bootstrap switch (diode).

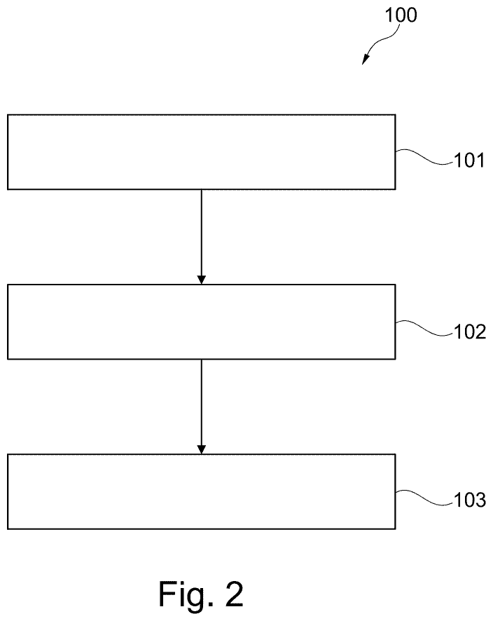

A method of fabricating an electrically conductive structure of a metallization structure of a semiconductor device will now be described with reference to FIG. 2. This method may be used to fabricate the contact pad 15 illustrated in FIG. 1.

FIG. 2 illustrates a flow diagram 100 of a method of fabricating an electrically conductive structure of a metallization structure.

In box 101, a metallic diffusion barrier layer is formed on a first major surface of a semiconductor substrate. Further layers of the metallization structure may be located between the metallic diffusion barrier layer and the first major surface of the semiconductor substrate. In this case, the metallic diffusion barrier layer is formed on this section of the metallization structure which has already been manufactured and which is located on the first major surface of the semiconductor substrate. For example, the metallic diffusion barrier layer may be formed directly on an electrically insulating layer, e.g. a silicon nitride layer, of the metallization structure. The metallic diffusion barrier layer may comprise WTi, Ti/TiN or TaN/Ta for example and may be fabricated by sputtering an alloy or multilayer stack.

In box 102, a structured copper layer is formed on the metallic diffusion barrier layer and portions of the metallic diffusion barrier layer are exposed from the structured copper layer, i.e. from the portions of the copper layer that are formed on regions of the metallic diffusion barrier layer. For example, the copper layer may be deposited by electroplating. In an embodiment, a seed layer is deposited onto the metallic diffusion barrier layer, for example by sputtering, a structured mask with one or more openings is deposited onto the seed layer, with the seed layer being exposed at the base of the one or more openings, and the copper layer is deposited by electroplating onto the seed layer and into the one or more openings of the mask. The seed layer may be formed of copper.

In box 103, the portions of the metallic diffusion barrier layer that are exposed from the structured copper layer, are removed by plasma etching. For example, the plasma etching may be carried out using SF₆ and N₂. Thus, one or more electrically conductive structures comprising the metallic diffusion barrier layer and the copper layer are formed. An electrically conductive structure may provide a contact pad or a redistribution interconnect. For example, the contact pad may be a source contact pad, a drain contact pad, a gate contact pad, an anode pad, a cathode pad, an input/output pad, an auxiliary pad, such as a source sense pad, a current sense pad or a kelvin pad or a pulldown gate pad. The redistribution interconnect may extend between two semiconductor devices or extend to a contact pad or provide a gate runner.

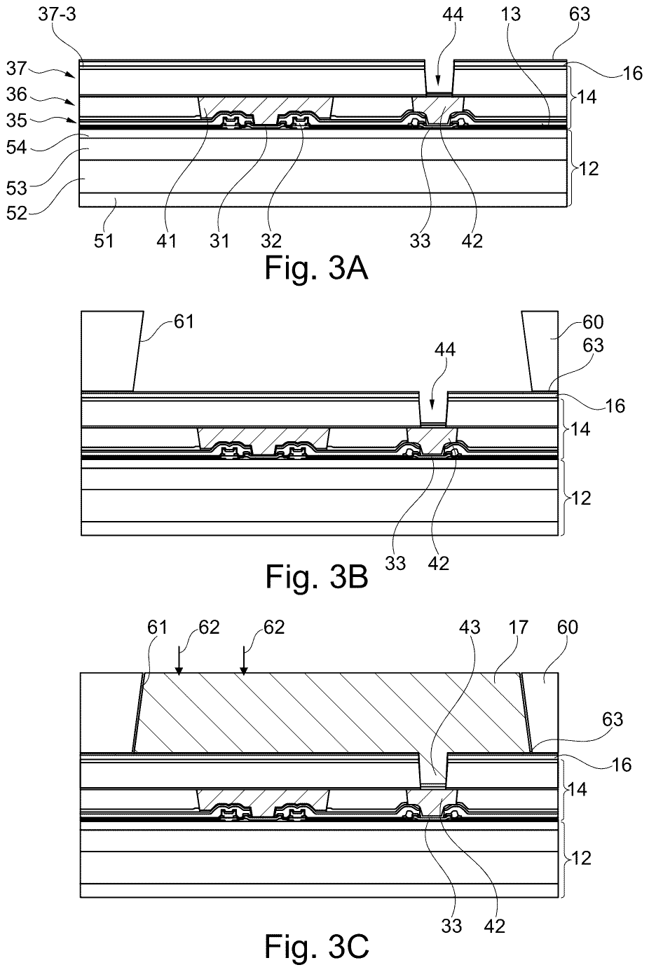

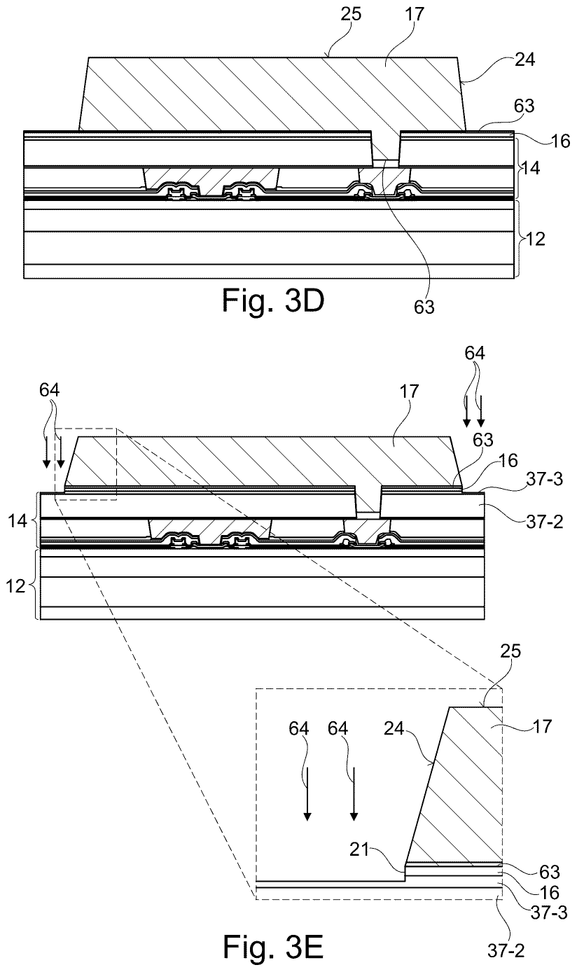

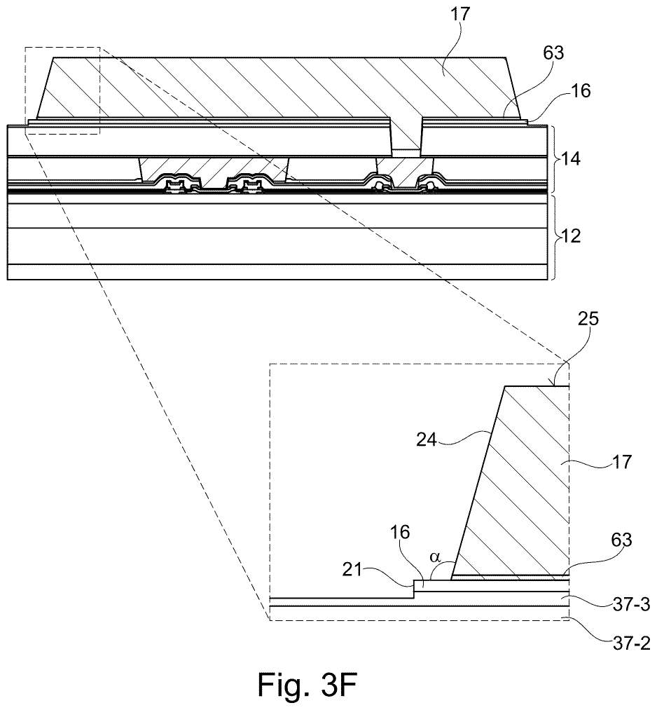

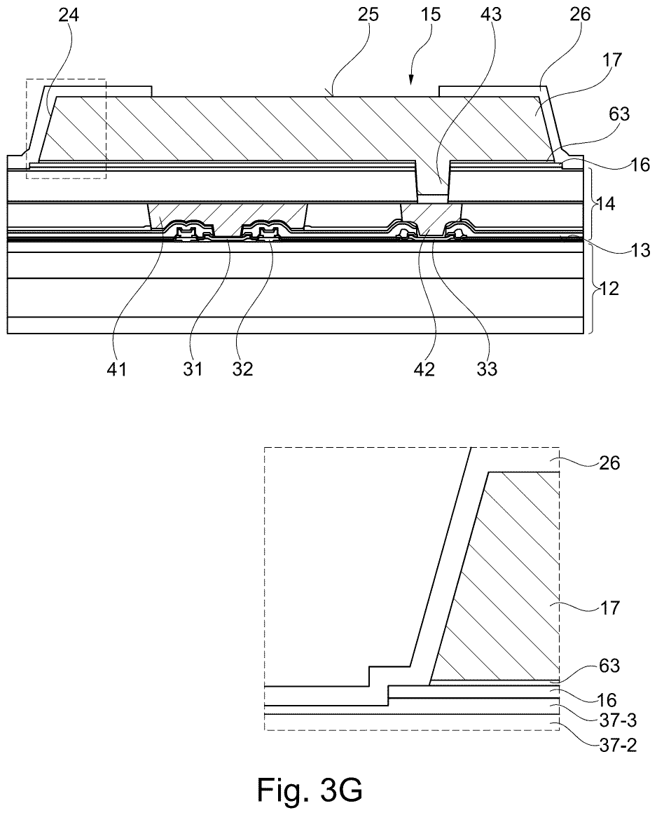

FIGS. 3A to 3G illustrates a method of fabricating an electrically conductive structure in the form of a contact pad 15 which is electrically connected to the drain electrode 33 of a lateral Group III nitride transistor device 30, in particular, a Group III nitride HEMT. However, the method may be used to fabricate other types of electric conductive structures, for example other types of contact pads and interconnects, and is not limited for use with Group III nitride-based devices, but may be used for devices formed in other semiconductor materials, such as silicon or silicon carbide. In FIGS. 3A to 3G, the metallization structure 14 is located on the first major surface 13 of the semiconductor substrate 12 is shown to have a certain number of electrically insulating and electrically conductive layers. However, the metallization structure 14 is not limited to illustrated structure and may be used for metallization structures with fewer or more than the illustrated number of electrically conductive layers and electrically insulating layers. The method may be used for the uppermost one of the conductive layers of the metallization structure of a semiconductor device. The uppermost conductive layer may be referred to as the power metal.

FIGS. 3A to 3G illustrates a fabrication of an electrically conductive structure 15 in the uppermost electrically conductive layer of the metallization structure 14 that is located on the first major surface 13 of the semiconductor substrate 12. In this embodiment, the partially fabricated metallization structure 14 has been built up on the first major surface 13 of the semiconductor device 30 and comprises first, second and third electrically insulating layers 35, 36, 37, as described with reference to FIG. 1, formed on a source electrode 31, a gate electrode 32 and a drain electrode 33 of a first electrically conductive layer, the second electrically conductive layer comprising a first redistribution portion 41 located in the second electrically insulating layer 36 which extends through the first electrically insulating layer 35 to the source electrode 31 and a second redistribution structure 42 located in the second electrically insulating layer 36 which extends through the first electrically insulative layer 35 to the drain electrode 32. The uppermost surface of the partially fabricated metallization layer 14 is provided by the upper nitride layer 37-3 in this embodiment.

Referring to FIG. 3A, the method proceeds by forming the metallic diffusion barrier layer 16 on the upper nitride sublayer 37-3. In some embodiments, a seed layer 63, e.g. a thin copper layer, is deposited on the diffusion metallic diffusion barrier layer 16. A seed layer 63 may be used if the copper layer 17 is to be deposited by electroplating. The seed layer 63 acts as an electrode in the electrolytic cell.

In some embodiments, an opening 44 is formed through the third electrically insulating layer 37 which exposes a portion of the second redistribution portion 42. The metallic diffusion layer 16 and seed layer 63 are then deposited so that the seed layer 63 and a metallic diffusion barrier layer is formed on the base of the opening 44 which is in direct contact with the second redistribution portion 42. Alternatively, the opening 44 is formed which extends through the copper seed layer 63, the metallic diffusion barrier layer 16 and the third electrically insulating layer 37 such that at least a portion of the second redistribution portion 42 is exposed at the base of the opening 44.

The copper seed layer 63 may be deposited by sputtering, for example, and may have a thickness of a few nanometres. The metallic diffusion barrier layer 16 may have a thickness of around 20 nm to 2 μm, for example around 300 nm.

Referring to FIG. 3B, a mask 60 is formed on the copper seed layer 63 which has at least one opening 61 exposing the copper seed layer 63 and the through opening 44. The opening 61 defines the location and lateral dimensions of the electrically conductive structure, e.g. contact pad 15, which is to be formed in the uppermost conductive layer of the metallization structure 14. The mask 60 may be formed of photoresist, for example, and be structured by photolithographic techniques.

Referring to FIG. 3C, copper 62 is deposited into the opening 61 which fills the through opening 44 so as to form the conductive via 43 between the contact pad 15 and the contact 42 to provide an electrically conductive redistribution structure for the drain electrode 33. In some embodiments, the copper 62 is deposited by electroplating onto the region of the copper seed layer 63 exposed in the opening 61. The copper seed layer 63 extends under the mask 60 over the entire area of the semiconductor device 10 and therefore serves to provide an electrode of the electrolytic cell for the electroplating method.

Referring to FIG. 3D, the mask 60 is then removed. The copper layer 17 may have its final dimensions or near final dimensions of the contact pad 15 at this stage and is located on the copper seed layer 63 extends over the entire surface of the metallization structure 14. The region of the copper seed layer 63 which was covered by the mask 61 is now exposed from and uncovered by the copper layer 17. The metallic diffusion barrier layer 16 also extends over the entire surface of the metallization structure 14.

Referring to FIG. 3E, and the enlarged view of the side face 24 of the contact pad 15, the exposed region of the copper seed layer 63 which was covered by the mask 61 is then removed, for example by wet etching. The wet etch selectively removes the copper seed layer 63 over the material of the metallic diffusion barrier layer 16. The seed layer 63 remains under the copper layer 17 and forms a part of the part contact pad 15. An example of a suitable wet etch comprises H₂O₂ (8.0%). The region of the metallic diffusion barrier layer 16, which was also located under the mask 61 and which is positioned laterally adjacent from the contact pad 15, is exposed. The exposed region of the metallic diffusion barrier layer 16 is then removed by plasma etching, as is schematically shown in FIG. 3E by the arrows 64. The plasma etching process may also remove an uppermost portion of the nitride layer 37-3. A portion of this nitride layer 37-3 remains, covering the underlying oxide layer 37-2. After plasma etching, the lateral extent of the metallic diffusion barrier layer 16 and the copper layer 17 of the contact pad 15 is substantially the same. Plasma etching conditions using SF₆ and N₂ gases may be used. The contact pad 15 may have a thickness of 50 nm to 20 μm, or 50 nm to 10 μm or 50 nm to 7 μm, for example.

During plasma etching of the exposed regions of the metallic diffusion barrier layer 16, the portions of the structured electroplated copper layer 17 act as a mask. The use of plasma etching to remove the exposed regions of the metallic diffusion barrier layer 16 enables the side face 21 of the covered or masked portion of the metallic diffusion barrier layer 16, which remains under the copper layer 17, to have a shape which is substantially vertical and substantially perpendicular to both the upper surface 20 and lower surface 23 of the metallic diffusion barrier layer 16, as can be seen more clearly in the enlarged view. Since the side face 21 may not be exactly perpendicular to the upper surface 20 and the lower surface 23 of the metallic diffusion barrier layer 16, variations from an exact vertical line are included so that a linear distance d between the upper edge 19 and the lower edge 22 is at most 10% or at most 5% greater than the thickness t of the metallic diffusion barrier layer 16, i.e. t≤d≤1.1 t or t≤d≤1.05 t.

FIG. 3F illustrates an optional process in which a further wet etching process is carried out. In this optional process, the upper surface 25 and side faces 24 of the copper layer 17 of the contact pad 15 are etched as is indicated schematically in FIG. 2F by the arrows 65. A selective wet etch may be used. As can be more easily seen in the enlarged view, the copper is selectively removed by wet etching such that a peripheral edge portion of the metallic diffusion barrier layer 16 is exposed and protrudes laterally beyond the maximum lateral extent of the copper layer 17. After the optional further wet etching process, the lateral extent of the metallic diffusion barrier of the contact pad 15 is greater than the lateral extent of the copper layer 17 of the contact pad 15.

The lowermost surface of the copper layer 17 may be laterally larger than the upper surface 25. The side face 21 of the metallic diffusion barrier layer 16 is positioned laterally outside of the maximum lateral extent of the copper layer 17 of that contact pad 15. The transition between the thicker and thinner portions of the uppermost nitride layer 37-3 is now also positioned laterally outside of the maximum lateral extent of the copper layer 17 and is substantially coplanar with the side face 24 of the metallic diffusion barrier layer 16. The additional etch process may, depending on the etching conditions, provide a transition between the copper layer 17 and the protruding peripheral edge portion of the metallic diffusion barrier layer 16 which is concave such that the angle formed at the interface between the copper layer 17 and the metallic diffusion barrier layer 16 is smaller. The angle α formed between the centre of the side face 24 of the copper layer 17 and the metallic diffusion barrier layer 16 may be greater than 90°, for example 105°.

Referring to FIG. 3G, a dielectric layer 26 is then deposited over at least the side faces 24 and upper surface 13 of the semiconductor substrate 12 such that the protruding portion of the metallic diffusion barrier layer 16, which is uncovered by the copper layer 17, is covered by the dielectric layer 26. The dielectric layer 26 may cover the entire metallization structure 14 apart from those regions of the one or more copper structures 15 which are provided for external contact 27, for example for solder contacts, bond wires, metallic ribbons or clips. In some embodiments, the dielectric layer 26 comprises two or more sublayers, for example three sublayers, e.g. a silicon nitride, silicon oxide, silicon nitride stack.

Typically, two or more electrically conductive structures 15 are formed. These electrically conductive structures 15 may be physically separate from one another and may be electrically isolated from one another, e.g. a source pad, a drain pad and a gate pad of the transistor device. In some embodiments, two or more electrically conductive structures may be integral, for example, a gate pad and an interconnect.

Whilst in the drawings, one electrically conductive structure in the form of the drain contact pad 15 is shown, the semiconductor device 10 also includes at least one further structure, e.g. at least one source contact pad and at least one gate contact pad and optionally one or more auxiliary pads and one or more interconnects, which may be fabricated using the same process steps as that of the drain contact pad 15 shown in the drawings. The source contact pad and the gate contact pad and any further auxiliary pads may have the same structure of the contact pad 15 with the copper layer 17 and the metallic diffusion barrier layer 16 shown in FIGS. 1 and 3.

The passivation integrity of the dielectric layer 26 deposited onto contact pad 15 with its the plasma etched metallic diffusion barrier layer 16 and copper layer 17 is improved, also in harsh environmental conditions. The upper dielectric layer 26 may be uniformly, continuously and uninterruptedly deposited onto the electrically conductive structure 15 due to the shape of the copper layer and exposed peripheral region of the metallic diffusion layer 16 with its substantially vertical side face. This assists in improving the integrity of the dielectric layer 26 during the operation lifetime of the semiconductor device 30 when thermomechanical stress is exerted on the passivation structure including the dielectric layer 26. The improved integrity of the dielectric layer 26 may assist in providing protection from mobile ions, such as chlorine ions, which may leak from the environment and/or the mold compound that is used to provide the housing of the package in which the semiconductor device 10 is mounted. Thus, electrical isolation of the contact pads 15 of the semiconductor device 10 from one another, e.g. the source and drain contact pads of a transistor device 10 which are typically connected to ground potential and a high potential, e.g. 650V in the case of some Group III nitride-based HEMTs, is improved.

Although the present disclosure is not so limited, the following numbered examples demonstrate one or more aspects of the disclosure.
1. A semiconductor device, comprising:
   i. a semiconductor substrate comprising a first major surface,
   ii. a metallization structure located on the first major surface, wherein the metallization structure comprises one or more electrically conductive structures,
   iii. wherein the electrically conductive structure comprises a metallic diffusion barrier layer and a copper layer located on the metallic diffusion barrier layer,
   iv. wherein the metallic diffusion barrier layer has a thickness t and a side face extending between an upper edge formed between an upper surface and the side face and a lower edge formed between a lower surface and the side face, wherein a linear distance d between the upper edge and the lower edge is t≤d≤1.1 t or t≤d≤1.05 t.
2. The semiconductor device according to example 1, wherein the side face extends substantially perpendicular to the first major surface.
3. The semiconductor device according to example 1 or example 2, wherein the metallic diffusion barrier layer has an upper surface and an opposing lower surface and the side face extends substantially perpendicular to the upper surface and the lower surface of the diffusion barrier layer.
4. The semiconductor device according to any one of examples 1 to 3, wherein the metallic diffusion barrier layer has a peripheral edge portion that protrudes from, and is uncovered by, the copper layer.
5. The semiconductor device according to any one of examples 1 to 3, wherein the copper layer has an upper surface and side faces extending from the upper surface to the metallic diffusion barrier layer.
6. The semiconductor device according to example 5, wherein the side face of the copper layer forms an angle with the upper surface of the metallic barrier layer that is greater than 90°.
7. The semiconductor device according to any one of examples 1 to 6, wherein a transition between the side face of the copper layer and the metallic barrier layer has a concave shape.
8. The semiconductor device according to any one of examples 1 to 7, wherein the metallic diffusion barrier layer comprises one of the group consisting of WTi, Ti/TiN and TaN/Ta.
9. The semiconductor device according to any one of examples 1 to 8, further comprising an upper dielectric layer arranged over a peripheral edge portion of the upper surface of the copper layer and the side faces of the copper layer.
10. The semiconductor device according to example 9, wherein the upper dielectric layer comprises two or more sublayers.
11. The semiconductor device according to example 10, wherein the upper dielectric layer comprises a first sublayer comprising a nitride, a second sublayer comprising an oxide on the first sublayer and a third sublayer comprising a nitride on the second sublayer.
12. The semiconductor device according to any one of examples 1 to 11, wherein the one or more electrically conductive structures comprise at least one of the group consisting of a contact pad and a redistribution interconnect.
13. The semiconductor device according to example 12, wherein the contact pad is a source contact pad, a drain contact pad, a gate contact pad, an anode pad, a cathode pad, an input/output pad, an auxiliary pad, such as a source sense pad, a current sense pad, a kelvin pad, or a pulldown gate pad, and/or wherein the redistribution interconnect extends between two semiconductor devices or extends to a contact pad.
14. The semiconductor device according to any one of examples 1 to 13, wherein the substrate comprises a semiconductor device structure.
15. The semiconductor device according to example 14, wherein the semiconductor device structure is a transistor device structure, a diode structure, a logic device, a gate driver, or a bootstrap switch.
16. The semiconductor device according to any one of examples 1 to 15, wherein the semiconductor substrate comprises Si, or SiC or comprises one or more Group III nitrides.
17. The semiconductor device according to any one of examples 1 to 16, herein the metallization structure further comprises one or more further conductive layers and one or more dielectric layers and the one or more electrically conductive structures are located in an uppermost further electrically conductive layer.
18. A method of fabricating an electrically conductive structure of a metallization structure, the method comprising:
   i. forming a metallic diffusion barrier layer on a first major surface of a semiconductor substrate;
   ii. forming a structured copper layer on the metallic diffusion barrier layer, wherein portions of the metallic diffusion barrier layer are exposed from the structured copper layer;
   iii. removing the exposed portions of the metallic barrier layer by plasma etching and
   iv. forming one or more electrically conductive structures comprising the metallic diffusion barrier layer and the copper layer.
19. The method according to example 18, further comprising:
   i. depositing a copper seed layer onto the metallic diffusion barrier layer, and then
   ii. depositing the copper layer onto the copper seed layer by electroplating.
20. The method according to example 18 or example 19, wherein the depositing the copper layer by electroplating comprises:
   i. forming a mask on the copper seed layer, the mask comprising at least one opening exposing the copper seed layer,
   ii. depositing the copper layer into the at least one opening and onto the exposed copper seed layer by electroplating.
21. The method according to any one of examples 18 to 20, further comprising:
   i. after forming the structured copper layer, removing the portions of the copper seed layer that are exposed from the structured copper layer by wet etching, and then
   ii. removing the exposed metallic barrier layer by plasma etching.
22. The method according to any one of examples 18 to 21, further comprising:
   i. performing a further etch process and removing a portion of the upper surface and side faces of the electrically conductive structure, and exposing a peripheral edge region of the metallic diffusion barrier layer from the copper layer of the electrically conductive structure.
23. The method according to example 22, wherein after the further etch process the side face of the copper layer of the electrically conductive structure forms an angle with the upper surface of the metallic barrier layer that is greater than 90°.
24. The method according to example 22 or example 23, wherein after the further etch process a transition between the copper layer and the metallic barrier layer of the electrically conductive structure has a concave shape.
25. The method according to any one of examples 18 to 24, wherein the metallization structure further comprises one or more further conductive layers and one or more dielectric layers and the one or more electrically conductive structures are located in an uppermost further electrically conductive layer.
26. The method according to any one of examples 18 to 25, wherein after the plasma etching the metallic diffusion barrier layer has a thickness t and a side face extending between an upper edge formed between an upper surface and the side face and a lower edge formed between a lower surface the side face, wherein the linear distance d between the upper edge and the lower edge is t≤d≤1.1 t or t≤d≤1.05 t.
27. The method according to example 26, wherein the side face of the metallic diffusion barrier layer is substantially perpendicular to the first major surface.
28. The method according to any one of examples 22 to 27, wherein the metallic diffusion barrier layer has a peripheral edge portion that protrudes from, and is uncovered by, the copper layer.
29. The method according to any one of examples 18 to 28, wherein after the plasma etching, the copper layer has an upper surface and side faces extending from the upper surface to the metallic diffusion barrier layer.
30. The method according to any one of examples 18 to 29, further comprising forming upper dielectric layer over a peripheral edge portion of the upper surface of the copper layer and the side faces of the copper layer.
31. The method according to example 30, wherein the upper dielectric layer comprises two or more sublayers.
32. The method according to example 30 or example 31, wherein the forming the upper dielectric layer comprises forming a first sublayer comprising a nitride, forming a second sublayer comprising an oxide on the first sublayer and forming a third sublayer comprising a nitride on the second sublayer.
33. The method according to any one of examples 18 to 32, wherein the metallic diffusion barrier layer comprises one of the group consisting of WTi, Ti/TiN, and TaN/Ta.
34. The method according to any one of examples 18 to 33, wherein the one or more electrically conductive structures comprise at least one of the group consisting of a contact pad and a redistribution interconnect.
35. The method according to example 34, wherein the contact pad is a source contact pad, a drain contact pad, a gate contact pad, an anode pad, a cathode pad, an input/output pad, an auxiliary pad, such as a source sense pad, a current sense pad or a kelvin pad.
36. The method according to any one of examples 18 to 35, wherein the substrate comprises a semiconductor device structure.
37. The method according to example 36, wherein the semiconductor device structure is a transistor device structure, a diode structure, a logic device, or a gate driver.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise. It is to be understood that the features of the various embodiments described herein may be combined with each other, unless specifically noted otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor substrate comprising a first major surface,
a metallization structure located on the first major surface, wherein the metallization structure comprises one or more electrically conductive structures,
wherein the one or more electrically conductive structures comprises a metallic diffusion barrier layer and a copper layer located on the metallic diffusion barrier layer,
wherein the metallic diffusion barrier layer has a thickness t and a side face extending between an upper edge formed between an upper surface and the side face and a lower edge formed between a lower surface and a side face,
wherein a linear distance d between the upper edge and the lower edge is t≤d≤1.1 t or t≤d≤1.05 t.

2. The semiconductor device of claim 1, wherein the metallic diffusion barrier layer has a peripheral edge portion that protrudes from, and is uncovered by, the copper layer.

3. The semiconductor device of claim 1, wherein the one or more electrically conductive structures comprises a contact pad and/or a redistribution interconnect.

4. The semiconductor device of claim 1, wherein the semiconductor substrate comprises at least one semiconductor device structure that comprises a transistor device structure, a diode structure, a logic device, a gate driver, or a bootstrap switch.

5. The semiconductor device of claim 1, wherein the semiconductor substrate comprises Si, SiC, or one or more Group III nitrides.

6. A method of fabricating an electrically conductive structure of a metallization structure, the method comprising:
forming a metallic diffusion barrier layer on a first major surface of a semiconductor substrate;
forming a structured copper layer on the metallic diffusion barrier layer, wherein portions of the metallic diffusion barrier layer are exposed from the structured copper layer;
removing the exposed portions of the metallic diffusion barrier layer by plasma etching; and
forming one or more electrically conductive structures comprising the metallic diffusion barrier layer and the copper layer.

7. The method of claim 6, further comprising:
depositing a copper seed layer onto the metallic diffusion barrier layer; and
subsequently depositing the copper layer onto the copper seed layer by electroplating.

8. The method of claim 7, wherein depositing the copper layer by electroplating comprises:
forming a mask on the copper seed layer, the mask comprising at least one opening exposing the copper seed layer; and
depositing the copper layer into the at least one opening and onto the exposed copper seed layer by electroplating.

9. The method of claim 6, further comprising:
after forming the structured copper layer, removing portions of the copper seed layer that are exposed from the structured copper layer by wet etching; and
subsequently removing the exposed metallic diffusion barrier layer by plasma etching.

10. The method of claim 6, further comprising:
performing a further etch process and removing a portion of the upper surface and side faces of the electrically conductive structure, and exposing a peripheral edge region of the metallic diffusion barrier layer from the copper layer of the electrically conductive structure.

11. The method of claim 10, wherein after the further etch process, the side face of the copper layer of the electrically conductive structure forms an angle with the upper surface of the metallic barrier layer that is greater than 90°.

12. The method of claim 6, wherein after the plasma etching, the metallic diffusion barrier layer has a thickness t and a side face extending between an upper edge formed between an upper surface and the side face and a lower edge formed between a lower surface and the side face, and wherein a linear distance d between the upper edge and the lower edge is t≤d≤1.1 t or t≤d≤1.05 t.

13. The method of claim 6, wherein after the plasma etching, the copper layer has an upper surface and side faces extending from the upper surface to the metallic diffusion barrier layer.

14. The method of claim 6, further comprising:
forming an upper dielectric layer arranged over a peripheral edge portion of the upper surface of the copper layer and the side faces of the copper layer of the one or more electrically conductive structures.

15. The method of claim 14, wherein forming the upper dielectric layer comprises:
forming a first sublayer comprising a nitride;
forming a second sublayer comprising an oxide on the first sublayer; and
forming a third sublayer comprising a nitride on the second sublayer.
